(19) United States
(12) Patent Application Publication
(10) Pub. No.: US 2023/0178339 A1
(43) Pub. Date: Jun. 8, 2023

(54) PLASMA PROCESSING APPARATUS AND MICROWAVE RADIATION SOURCE

(71) Applicant: Tokyo Electron Limited, Tokyo (JP)

(72) Inventors: Kenta KATO, Nirasaki City (JP); Taro IKEDA, Nirasaki City (JP); Isao GUNJI, Nirasaki City (JP)

(21) Appl. No.: 17/994,711

(22) Filed: Nov. 28, 2022

(30) Foreign Application Priority Data
Dec. 2, 2021 (JP) 2021-196368

(51) Int. Cl. H01J 37/32

(52) U.S. Cl. CPC H01J 37/32201; H01J 37/32238; H01J 2237/327

(57) ABSTRACT

A plasma processing apparatus includes a processing container including an opening provided in a ceiling wall of the processing container, and a microwave radiation source. The microwave radiation source includes a slot antenna including a slot and configured to radiate microwaves from the slot, and a transmission window configured to close the opening and to radiate the microwaves from the slot into the processing container. The transmission window includes a first surface including a skirt which suspends to cover a side wall of the opening, and a second surface which is an opposite surface to the first surface and faces the slot antenna with a gap between the slot antenna and the second surface.

### CROSS-REFERENCE TO RELATED APPLICATION

This application is based upon and claims the benefit of priority from Japanese Patent Application No. 2021-196368, filed on Dec. 2, 2021, the entire contents of which are incorporated herein by reference.

### TECHNICAL FIELD

The present disclosure relates to a plasma processing apparatus and a microwave radiation source.

### BACKGROUND

For example, Patent Document 1 proposes a plasma processing apparatus in which no unevenness is present on the bottom surface of a transmission window provided in an opening in the ceiling wall of a processing container, and a protrusion is present on the bottom surface of the ceiling wall, along which surface waves of microwaves radiated from a microwave radiation member propagate.

Patent Document 2 proposes a plasma processing apparatus which includes a stage on which a wafer is placed in a chamber, a planar antenna member having a plurality of microwave transmission holes and configured to introduce microwaves into the chamber, and a transmission plate which partitions a plasma processing space formed between the planar antenna member and the stage. The transmission plate has a protrusion formed on the bottom surface thereof.

### PRIOR ART DOCUMENTS

### Patent Documents

Patent Document 1: Japanese Laid-Open Publication No. 2019-106358
Patent Document 2: Japanese Laid-Open Publication No. 2007-294924

### SUMMARY

According to an embodiment of the present disclosure, there is provided a plasma processing apparatus including: a processing container including an opening provided in a ceiling wall of the processing container; and a microwave radiation source, wherein the microwave radiation source includes: a slot antenna including a slot and configured to radiate microwaves from the slot; and a transmission window configured to close the opening and to radiate the microwaves from the slot into the processing container, and wherein the transmission window includes: a first surface including a skirt which suspends to cover a side wall of the opening; and a second surface which is an opposite surface to the first surface and faces the slot antenna with a gap between the slot antenna and the second surface.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a plasma processing apparatus according to an embodiment.

FIGS. 2A to 2C are views illustrating an example of the configuration and matching positions of a transmission window according to a reference example.

FIGS. 3A to 3C are views illustrating an example of the configuration and matching positions of a transmission window according to a first embodiment.

FIG. 4 is a view illustrating an example of experimental results of the numbers of contaminations in the configuration of the transmission window of the first embodiment.

FIGS. 5A to 5C are views illustrating an example of the configuration and matching positions of a transmission window according to a second embodiment.

FIGS. 6A and 6B are views showing an example of experimental results of ignitability in the configurations of the transmission windows of the second to third embodiments and the reference example.

FIGS. 7A to 7C are views illustrating an example of the configuration of a microwave radiation source according to a third embodiment.

FIGS. 8A to 8C are views illustrating an example of the configuration and matching positions of a transmission window according to a third embodiment.

FIGS. 9A to 9C are views illustrating an example of results of electromagnetic system simulation in the transmission window according to the third embodiment.

### DETAILED DESCRIPTION

Hereinafter, embodiments of the present disclosure will be described with reference to the accompanying drawings. In each of the drawings, the same components may be denoted by the same reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In this specification, in the directions of parallel, right angle, orthogonal, horizontal, vertical, up and down, left and right, and the like, a deviation that does not impair the effect of an embodiment is allowed. The shape of a corner portion is not limited to a right angle, and may be rounded in a bow shape. Parallel, perpendicular, orthogonal, horizontal, vertical, circular, and coincident may include substantially parallel, substantially perpendicular, substantially orthogonal, substantially horizontal, substantially vertical, substantially circular, and substantially coincident.

### [Plasma Processing Apparatus]

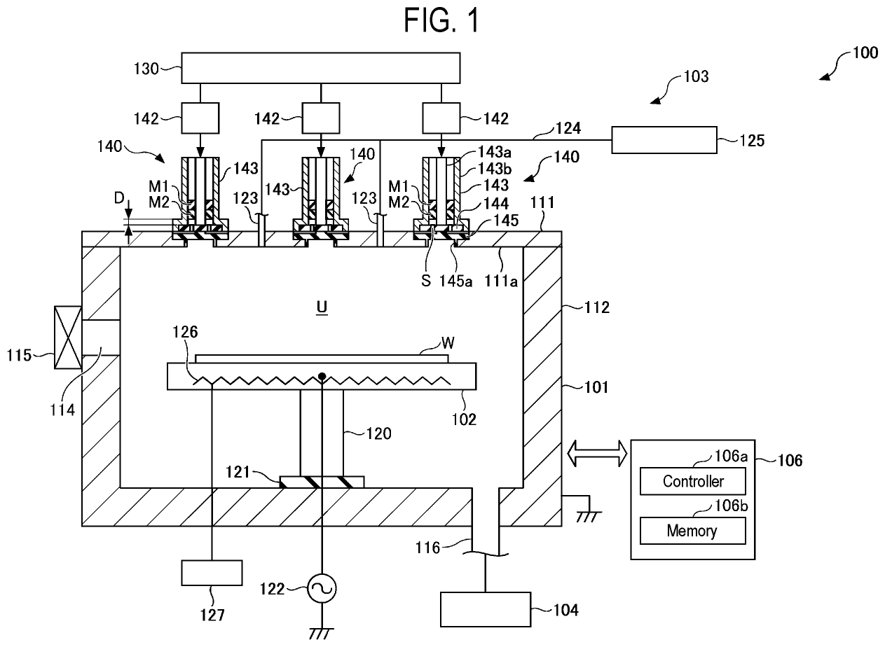

An example of a plasma processing apparatus according to an embodiment will be described. FIG. 1 is a schematic cross-sectional view illustrating an example of a plasma processing apparatus 100 according to an embodiment. The plasma processing apparatus 100 includes a processing container 101, a stage 102, a gas supply part 103, an exhaust device 104, a microwave radiation source 140, and a control part 106.

The processing container 101 is made of a metal material such as aluminum having a surface subjected to coating treatment with yttria (Y₂O₃) or the like and includes a bottomed cylindrical container main body 112 and a ceiling wall 111. The upper portion of the container main body 112 is open, and a disk-shaped ceiling wall 111 closes the opening. This allows the airtightness of a plasma processing space U in the processing container 101 to be maintained. The stage 102 is disposed at the bottom in the processing container 101.

The stage 102 has a disk shape and is made of a metal material such as aluminum having an anodized surface, or a ceramic material such as aluminum nitride (AlN). A substrate W such as a semiconductor wafer is placed on the stage 102. The stage 102 is supported by, for example, a metallic support member 120 extending upward from the bottom of the container main body 112 via an insulating member 121.

Inside the stage 102, lifting pins (not illustrated) for raising and lowering a substrate W are provided to be capable of protruding and sinking with respect to the top surface of the stage 102. In addition, a heater 126 is provided inside the stage 102 as heating means. The heater 126 is powered by a heater power supply 127 to generate heat. By controlling the output of the heater 126 based on a temperature signal from a sensor (e.g., a thermocouple) provided near the top surface of the stage 102, the substrate W is heated to a predetermined temperature.

A high-frequency power supply 122 is electrically connected to the stage 102. When the stage 102 is made of ceramic, an electrode is provided on the stage 102, and the high-frequency power supply 122 is electrically connected to the electrode. The high-frequency power supply 122 applies high-frequency power as bias power to the stage 102. The frequency of the high-frequency power applied by the high-frequency power supply 122 is preferably in the range of 0.4 to 27.12 MHz.

An exhaust pipe 116 is provided at the bottom of the container main body 112, and an exhaust device 104 is connected to the exhaust pipe 116. The exhaust device 104 includes a vacuum pump, a pressure control valve, and the like, and the interior of the processing chamber 101 is exhausted by the vacuum pump through the exhaust pipe 116 to be controlled to a desired vacuum state. The pressure inside the processing container 101 is controlled by the pressure control valve based on the value of a pressure gauge (not illustrated). The side wall of the container main body 112 is provided with a carry-in/out port 114 for performing carry-in/out of a substrate W to/from a transport chamber (not illustrated) adjacent to the processing container 101. At the time of carry-in/out of a substrate W, the carry-in/out port 114 is opened by a gate valve 115 provided along the side wall of the container main body 112.

The ceiling wall 111 includes a plurality of openings each for disposing a microwave radiation source 140 or a gas introduction pipe 123. The gas supply pipe 103 includes a plurality of gas introduction pipes 123, a gas supply pipe 124, and a gas source 125. The plurality of gas introduction pipes 123 are disposed in a plurality of openings, respectively, which are formed around a central microwave radiation source 140 in the ceiling wall 111. The plurality of gas introduction pipes 123 are connected to the gas source 125 via the gas supply pipe 124.

The gas source 125 supplies various processing gases. The gas supply pipe 124 is provided with a valve configured to control the supply and stop of the supply of a processing gas or a flow adjuster configured to adjust the flow rate of the processing gas.

The microwave radiation source 140 is disposed in each of six openings (of which only two are illustrated in FIG. 1) on the outer periphery of the ceiling wall 111 and one opening in the center of the ceiling wall 111. That is, in the present embodiment, seven microwave radiation sources 140 are arranged on the ceiling wall 111 to be inserted into respective openings in the ceiling wall 111. However, the number and arrangement of the microwave radiation sources 140 are not limited to this. For example, only one microwave radiation source 140 may be arranged in the center, or two or more microwave radiation sources may be arranged only in the periphery of the ceiling wall 111.

The microwave radiation sources 140 are connected to a microwave output part 130 via amplifiers 142. The microwave output part 130 generates microwaves, distributes the microwaves, and outputs the distributed microwaves to each amplifier 142. Each amplifier 142 mainly amplifies the distributed microwaves and outputs the amplified microwaves to each microwave radiation source 140.

Each of the microwave radiation sources 140 has an antenna module 143, a slot antenna 144, and a transmission window 145. The antenna module 143 is a coaxial waveguide including an inner conductor 143a and an outer conductor 143b disposed concentrically around the inner conductor 143a, and microwaves propagate in the space between the inner conductor 143a and the outer conductor 143b. Annular dielectric members M1 and M2 are provided up and down in the space between the inner conductor 143a and the outer conductor 143b. The dielectric member M1 is disposed above the dielectric member M2. The dielectric members M1 and M2 are vertically movable to adjust impedance. The configuration of the transmission window 145 will be described later in the order of the first embodiment, the second embodiment, and the third embodiment.

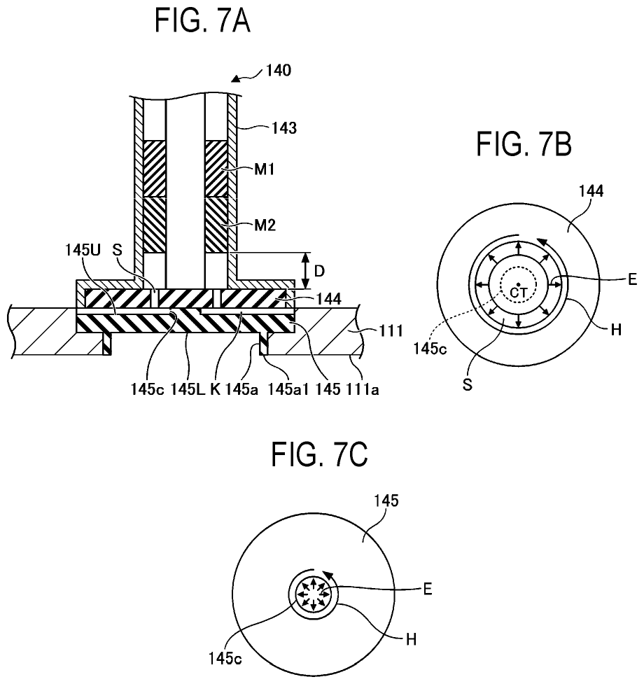

The tip of the outer conductor 143b (the tip of the antenna module 143) is expanded in diameter. A disk-shaped slot antenna 144 is fitted inside the enlarged diameter of the outer conductor 143b. The outer conductor 143b and the slot antenna 144 are provided above (outside) the ceiling wall 111. The inner conductor 143a abuts on the center of the top surface of the slot antenna 144. The slot antenna 144 includes an arcuate or annular slot S around the central portion of the slot antenna 144 (see FIG. 7B). The slot antenna 144 has a function of an antenna that radiates microwaves from the slot S. The slot S may be formed in an arcuate or annular shape around the central portion of the slot antenna 144.

A transmission window 145, which radiates microwaves radiated from the slot S into the processing container 101, is provided below the slot antenna 144. The transmission window 145 is disposed inside the opening provided in the ceiling wall 111 and closes the opening. The transmission window 145 is made of a dielectric material such as alumina (Al₂O₃) and transmits microwaves. Thus, microwave radiation source 140 radiates microwaves into the processing container 101.

The control part 106 is, for example, a computer including a controller 106a and a memory 106b. The control part 106 may include an input device, a display device, and the like. The controller 106a controls each part of the plasma processing apparatus 100. In the controller 106a, an operator may perform a command input operation or the like by using an input device in order to manage the plasma processing apparatus 100. The controller 106a may visualize and display the operation situation of the plasma processing apparatus 100 by using a display device. The memory 106b stores control programs and recipe data for controlling various processes executed in the plasma processing apparatus 100 by the controller 106a. The controller 106a executes a control program to control each part of the plasma processing apparatus 100 according to recipe data, thereby performing substrate processing such as film formation by using the plasma processing apparatus 100.

### First Embodiment

### [Transmission Window]

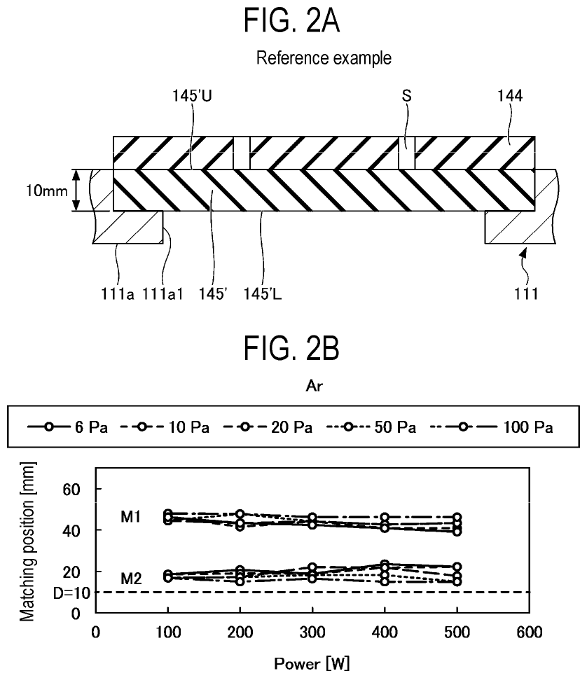

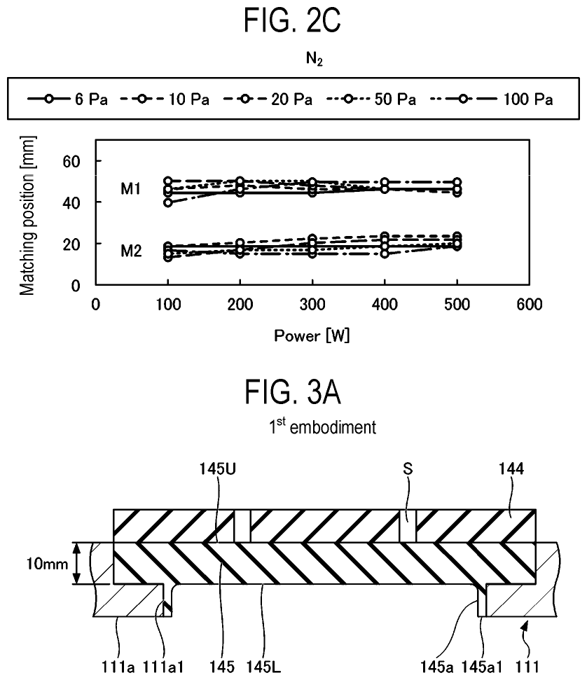

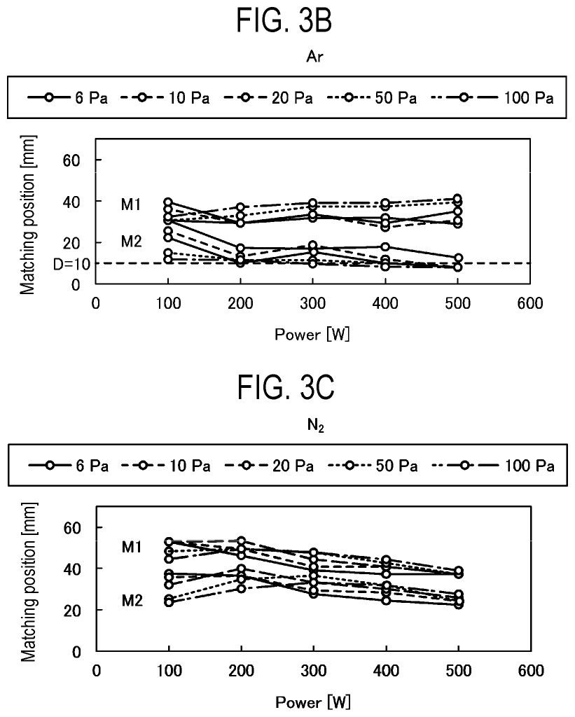

Next, details of the configuration of the transmission window 145 according to a first embodiment will be described with reference to FIGS. 2A to 2C and FIGS. 3A to 3C. FIG. 2A is a view illustrating the configuration of a transmission window 145′ according to a reference example. FIG. 3A is a view illustrating the configuration of a transmission window 145 according to the first embodiment.

In both the reference example of FIG. 2A and the first embodiment of FIG. 3A, a slot antenna 144 and the transmission windows 145′ and 145 are disk-shaped with the same diameter. That is, the positions of the side walls of the slot antenna 144 and the transmission window 145′ are aligned with each other, and the positions of the side walls of the slot antenna 144 and the transmission window 145 are aligned with each other. However, having the same diameter is not an essential condition. The side wall 111a1 of the opening in the ceiling wall 111 is exposed.

In the transmission window 145′ of the reference example of FIG. 2A, both the bottom surface 145′L and the top surface 145′U are flat, and the top surface 145′U of the transmission window 145′ is in contact with the slot antenna 144. The thickness of the transmission window 145′ is constant. Meanwhile, in the transmission window 145 of the first embodiment illustrated in FIG. 3A, a first surface 145L, which is the bottom surface of the transmission window 145, includes a skirt 145a which suspends to cover the side wall 111a1 of the opening in the ceiling wall 111. The thickness of the transmission window 145 is constant except for the skirt 145a. A second surface 145U, which is the top surface of the transmission window 145, is flat and is in contact with the slot antenna 144. The skirt 145a is formed inside the side wall of the transmission window 145.

In the configuration of the transmission window 145′ of the reference example of FIG. 2A, electric fields due to electromagnetic waves radiated from the transmission window 145′ concentrate at the corner of the side wall 111a1 of the opening in the ceiling wall 111, or in the vicinity thereof. Thus, a high electric field is generated near the opening of the ceiling wall 111, and thus the ceiling wall 111 is damaged. Due to the damage, a thermally sprayed yttria film on the surface of the ceiling wall 111 is worn away, and the internal aluminum is scraped off by being exposed to plasma, resulting in contamination of yttrium or aluminum. Metal contamination in such a processing container 101 has been a problem.

In order to avoid damage to the corner of the side wall 111a1 of the opening in the ceiling wall 111 or the vicinity thereof and to avoid the occurrence of contamination, the transmission window 145 of the first embodiment illustrated in FIG. 3A is provided with a skirt 145a which suspends to cover the side wall 111a1 of the opening. The skirt 145a covers the side wall 111a1 of the opening at the outer circumference side of the slot S over the entire circumference of the side wall Mal. In addition, the height of the end 145a1 of the skirt 145a is aligned with the height of the end of the opening. That is, the end portion of the opening and the end 145a1 of the skirt 145a is aligned with the height of the lower surface 111a of the ceiling wall 111.

This makes it possible to avoid electric field concentration on the corner of the side wall 111a1 of the opening or the vicinity thereof by the skirt 145a, and to prevent or suppress damage to the vicinity of the opening in the ceiling wall 111. This makes it possible to reduce the occurrence of metal contamination.

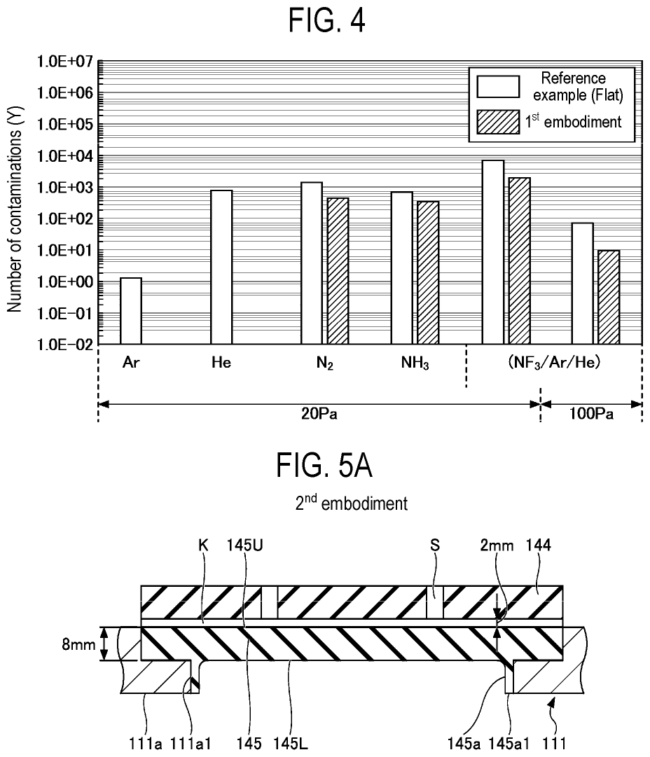

FIG. 4 shows an example of experimental results which show, in a comparative manner, the numbers of yttrium (Y) precipitated as metal contaminations from yttria of films thermally sprayed to the surface of the ceiling wall 111, in the case where the transmission window 145 of the first embodiment was used and the numbers of yttrium (Y) precipitated as metal contamination, in the case where the transmission window 145′ of the reference example was used.

The results in FIG. 4 show that, in either case of any of a N₂ gas, a NH₃ gas, or a mixed gas of NF₃/Ar/He, the numbers of contaminations in the case where the transmission window 145 of the first embodiment when plasma was generated were less than those in the case where the transmission window 145′ of the reference example was used. The interior of the processing container 101 was controlled to 20 Pa when plasma of the N₂ gas and the NH₃ gas was generated. When the plasma of the mixed gas of NF₃/Ar/He was generated, the interior of the processing container 101 was controlled to 20 Pa and 100 Pa. In either case, by using the configuration of the transmission window 145 of the first embodiment, it was possible to reduce the occurrence of metal contamination compared to the reference example.

However, in the transmission window 145 of the first embodiment illustrated in FIG. 3A, since the shape of the transmission window was changed by providing the skirt 145a, the range of plasma use conditions (process use conditions) became narrower compared to the transmission window 145′ of the reference example of FIG. 2A. The results will be described with reference to FIGS. 2B and 2C and FIGS. 3B and 3C. The thickness of the transmission window 145′ is 10 mm, and the thickness of the transmission window 145 is 10 mm, except for the skirt 145a.

In each of FIGS. 2B and 3B, the horizontal axis represents the power W of microwaves introduced from the transmission windows 145 and 145′ while the interior of the processing container 101 was controlled to 6 Pa, 10 Pa, 20 Pa, 50 Pa, and 100 Pa. In addition, the vertical axis represents the matching positions (mm) of the dielectric members M1 and M2 when Ar gas plasma was generated.

In each of FIGS. 2C and 3C, the horizontal axis represents the power (W) of microwaves introduced from the transmission windows 145 and 145′ while the interior of the processing container 101 was controlled to 6 Pa, 10 Pa, 20 Pa, 50 Pa, and 100 Pa. The vertical axis represents the matching positions (mm) of the dielectric members M1 and M2 when N₂ gas plasma was generated.

As a result of experiments, when the transmission window 145′ of the reference example was used, as shown in FIGS. 2B and 2C, the matching positions of the dielectric members M1 and M2 were not substantially changed even when the power of microwaves or pressure were changed. This indicates that the plasma is stable. In other words, it indicates that the range of plasma use conditions is wide.

In contrast, when the transmission window 145 of the first embodiment was used, as shown in FIGS. 3B and 3C, the matching positions of the dielectric members M1 and M2 were changed when the power of microwaves or pressure was changed, and variations were caused. This indicates that plasma is unstable. In other words, it indicates that the range of plasma use conditions is narrow.

In addition, assuming that the distance from the bottom surface of the dielectric member M2 to the top surface of the slot antenna 144 is D (see FIGS. 1 and 7A), when the distance D at the matching position of the dielectric member M2 is less than 10 mm, there is a possibility of contact since the distance from the dielectric member M2 to the slot antenna 144 is short. That is, it indicates that, since it is impossible to further move the dielectric member M2 toward the slot antenna 144, it is impossible to achieve matching. In other words, it indicates that the range of plasma use conditions is narrow.

Regarding this point, when the transmission window 145′ of the reference example was used, the matching position (distance D) of the dielectric member M2 exceeded 10 mm as shown in FIG. 2B. In contrast, when the transmission window 145 of the first embodiment was used, the matching position (distance D) of the dielectric member M2 was less than 10 mm as shown in FIG. 3B. Consequently, in the transmission window 145 of the first embodiment illustrated in FIG. 3A, plasma became unstable and thus the range of plasma use conditions became narrower compared to the transmission window 145′ of the reference example illustrated in FIG. 2A.

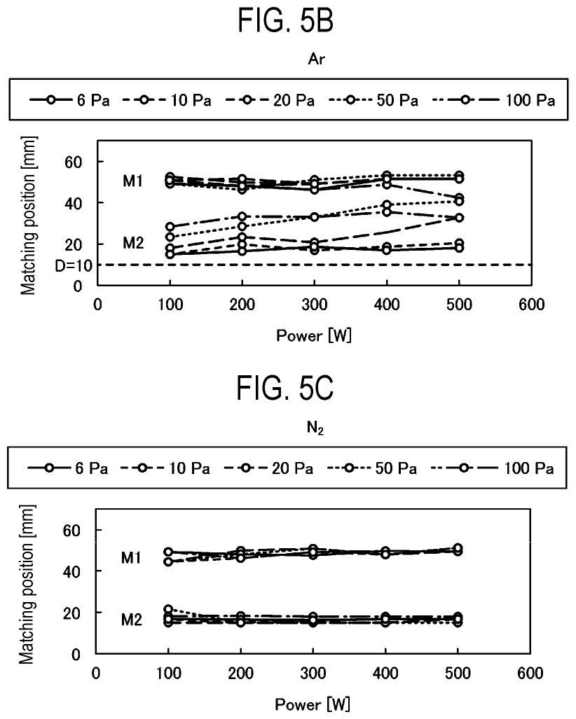

Therefore, the shape of the transmission window 145 was improved in order to make the range of plasma use conditions wider than that in the case where the transmission window 145 of the first embodiment is used, and to avoid damage to the ceiling wall 111 and to suppress the occurrence of contamination. The configuration of a transmission window 145 of a second embodiment after improvement will be described with reference to FIGS. 5A to 5C.

### Second Embodiment

### [Transmission Window]

FIG. 5A is a view illustrating an example of the configuration and matching position of the transmission window 145 according to the second embodiment. The transmission window 145 of the second embodiment has basically the same configuration as that of the first embodiment, and the configuration different from that of the transmission window 145 of the first embodiment will be described below, and the description of the same configuration will be omitted.

The transmission window 145 according to the second embodiment includes a first surface 145L including a skirt 145a which suspends to cover the side wall 111a1 of the opening, and a second surface 145U which is an opposite surface to the first surface 145L and faces the slot antenna 144 with a gap K therebetween. The slot antenna 144 and the second surface 145U are not in contact with each other, and there is a gap K of 2 mm in the vertical direction therebetween. The thickness of the transmission window 145 is 8 mm except for the skirt 145a. However, the gap K may be 2 mm or less in the vertical direction.

In each of FIGS. 5B and 5C, the power of microwaves introduced from the transmission window 145 of the second embodiment by controlling the interior of the processing container 101 to 6 Pa, 10 Pa, 20 Pa, 50 Pa, and 100 Pa is represented on the horizontal axis. In addition, in FIG. 5B the matching positions of the dielectric members M1 and M2 when Ar gas plasma was generated are represented on the vertical axis, and in FIG. 5C, the matching positions of the dielectric members M1 and M2 when N₂ gas plasma was generated are represented on the vertical axis.

As a result of experiments, in the case where the transmission window 145 of the second embodiment was used, when Ar gas plasma was generated as shown in FIG. 5B, the matching position of the dielectric member M1 was not substantially changed even when the power of microwaves or pressure was changed. Although the matching position of the dielectric member M2 slightly fluctuated, the matching position of the dielectric member M2 (distance D: see FIG. 7A) exceeded 10 mm. This indicates that the plasma is stable.

When N₂ gas plasma was generated as shown in FIG. 5C, the matching positions of the dielectric members M1 and M2 were not substantially changed even when the power of microwaves or pressure was changed. This indicates that the plasma is stable. In other words, it indicates that the range of plasma use conditions is wide.

Consequently, when the transmission window 145 of the second embodiment was used, the plasma was stabilized compared to the case where the transmission window 145 of the first embodiment was used, and thus it was possible to widen the range of plasma use conditions. Therefore, with the transmission window 145 of the second embodiment, it is possible to prevent or suppress damage to the ceiling wall 111 and to reduce the occurrence of metal contamination while maintaining the range of plasma use conditions widely.

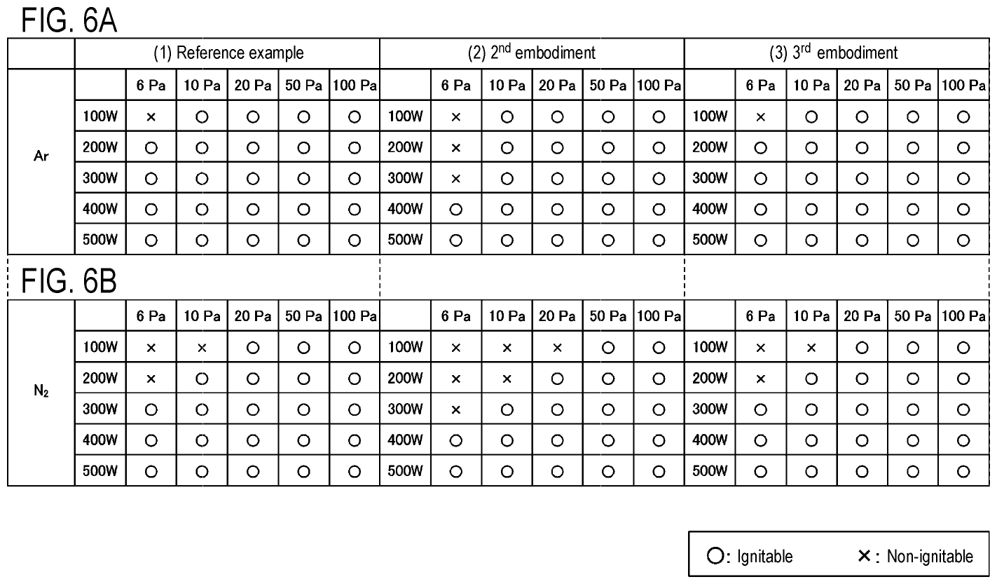

Meanwhile, in the experimental results of plasma ignitability, when the transmission window 145 of the second embodiment was used, the plasma ignitability was poor compared to that in the case where the transmission window 145′ of the reference example was used. FIGS. 6A and 6B are views showing an example of experimental results of ignitability in the configurations of the transmission windows of the second to third embodiments and the reference example.

FIG. 6A shows the states of plasma ignition when Ar gas plasma was generated. FIG. 6B shows the states of plasma ignition when N₂ gas plasma was generated. Plasma ignitability was determined visually.

In these experimental results, regarding the case where the transmission window 145′ according to the reference example was used in FIG. 6A and the case where the transmission window 145 according to the second embodiment was used in FIG. 6B, for each pressure and for each microwave power, ∘ (ignitable) is indicated when ignition occurred and x (non-ignitable) is indicated when ignition did not occur. The case where the transmission window 145 according to the second embodiment shown in a section (3) of FIGS. 6A and 6B was used will be described later. In the case where the transmission window 145 according to the second embodiment of the section (2) of FIGS. 6A and 6B was used, the plasma ignition became worse in either of FIG. 6A or FIG. 6B compared to the case where the transmission window 145′ according to the reference example shown in the section (1) of FIGS. 6A and 6B.

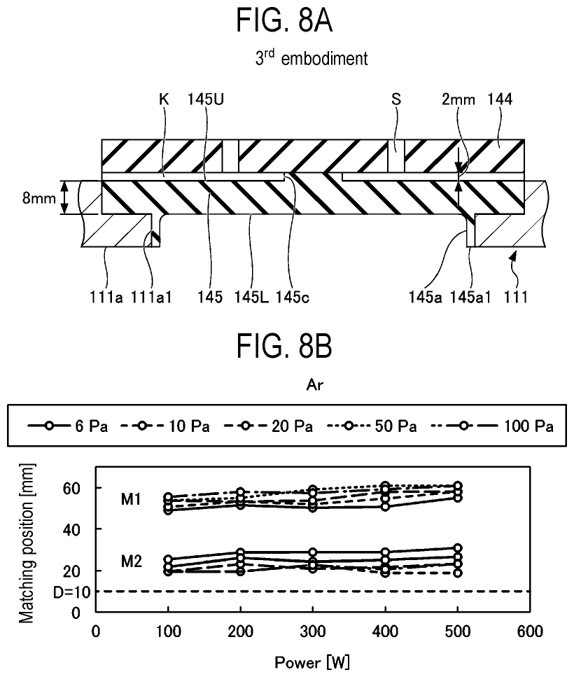

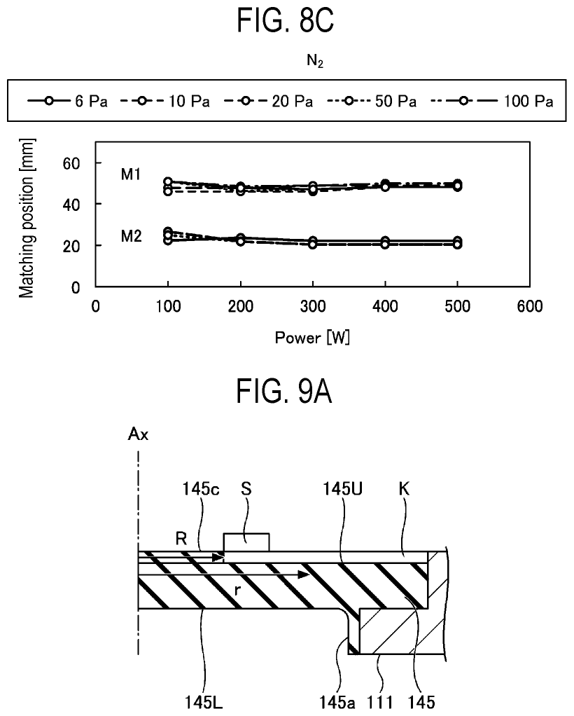

Therefore, the shape of the transmission window 145 was further improved so as to avoid damage to the ceiling wall 111 and to suppress the occurrence of metal contamination while maintaining the range of plasma use conditions and plasma ignition performance. The configuration of the transmission window 145 of a third embodiment after the improvement will be described with reference to FIGS. 7A to 7C and FIGS. 8A to 8C.

### Third Embodiment

### [Transmission Window]

FIGS. 7A to 7C are cross-sectional schematic views illustrating an example of a microwave radiation source 140 including a transmission window 145 according to the third embodiment. FIGS. 8A to 8C are views illustrating an example of the configuration and matching positions of the transmission window 145 according to the third embodiment. The transmission window 145 of the third embodiment has basically the same configuration as that of the second embodiment, and the configuration different from that of the transmission window 145 of the second embodiment will be described below, and the description of the same configuration will be omitted.

As illustrated in FIGS. 7A and 8A, the transmission window 145 according to the third embodiment includes a first surface 145L having a skirt 145a which suspends to cover the side wall 111a1 of the opening. The transmission window 145 further includes a second surface 145U, which is an opposite surface to the first surface 145L and faces the slot antenna 144 with a gap K therebetween. The second surface 145U includes a protrusion 145c which is in contact with the central portion of the slot antenna 144, and is configured to face the slot antenna 144 with a gap K therebetween on the surface other than the protrusion 145c. That is, the second surface 145U is not in contact with the slot antenna 144 except for the protrusion 145c, and there is a gap K of 2 mm in the vertical direction therebetween. The thickness of the transmission window 145 is 8 mm except for the skirt 145a.

FIG. 7B illustrates the positional relationship between the second surface 145U of the transmission window 145 and the rear surface of the slot antenna 144 facing the same, and FIG. 7C illustrates the second surface 145U. As illustrated in FIG. 7B, in the present disclosure, the slot S of the slot antenna 144 is an annular opening having predetermined inner and outer diameters from the center CT. The inner side of the inner diameter of the slot S is the central portion of the slot antenna 144 that includes a contact portion with the protrusion 145c.

For example, in the present disclosure, the protrusion 145c has a cylindrical shape with a radius R from the center of the transmission window 145 and a height of 2 mm. The top surface of the protrusion 145c is a surface that is in contact with the slot antenna 144, and is a circle having a diameter (2R) smaller than the inner diameter of the slot S. In this case, as illustrated in FIG. 7B, the top surface of the protrusion 145c is in contact with the central portion of the slot antenna 144 to be spaced apart from the slot S.

However, without being limited thereto, the top surface of the protrusion 145c may be a circle having a diameter (2R) equal to or less than the inner diameter of the slot S. For example, the diameter of the top surface of the protrusion 145c and the inner diameter of the slot S may coincide with each other. In this case, the top surface of the protrusion 145c does not overlap the inner portion of the slot S. In other words, the top surface of the protrusion 145c is not visible through the slot S. Meanwhile, when the diameter of the top surface of the protrusion 145c is larger than the inner diameter of the slot S, the top surface of the protrusion 145c overlaps the inner portion of the slot S, which is not allowed. In addition, in the present disclosure, the height of the protrusion is 2 mm, but may be 2 mm or less.

In each of FIGS. 8B and 8C, the power of microwaves introduced from the transmission window 145 of the third embodiment by controlling the interior of the processing container 101 to 6 Pa, 10 Pa, 20 Pa, 50 Pa, and 100 Pa is represented on the horizontal axis. In addition, in FIG. 8B, the matching positions of the dielectric members M1 and M2 when Ar gas plasma was generated are represented on the vertical axis, and in FIG. 8C, the matching positions of the dielectric members M1 and M2 when N₂ gas plasma was generated are represented on the vertical axis.

As a result of the experiment, in the case where the transmission window 145 of the third embodiment was used, when either Ar gas plasma or N₂ gas plasma was generated as shown in FIGS. 8B and 8C, the matching positions of the dielectric members M1 and M2 were not substantially changed even if the power of microwaves or pressure was changed. This indicates that the plasma is stable. In other words, it indicates that the range of plasma use conditions is wide. In addition, when the transmission window 145 of the third embodiment was used, the matching position (distance D) of the dielectric member M2 was less than 10 mm as shown in FIG. 8B. This indicates that the plasma is stable.

Further, reference is made to the experimental results of plasma ignitability in FIGS. 6A and 6B. In the case where the transmission window 145 according to the third embodiment illustrated in the section (3) of FIGS. 6A and 6B, plasma ignition performance was improved for both the gases in FIGS. 6A and 6B compared to that in the case where the transmission window 145 according to the second embodiment illustrated in the section (2) of FIGS. 6A and 6B. When the transmission window 145 according to the third embodiment illustrated in the section (3) of FIGS. 6A and 6B was used, it was possible to improve the plasma ignitability to the same level as that in the case where the transmission window 145′ according to the reference example illustrated in the section (1) of FIGS. 6A and 6B was used.

Consequently, when the transmission window 145 of the third embodiment was used, the plasma was stabilized as in the case where the transmission window 145 of the second embodiment was used, and thus it was possible to widen the range of plasma use conditions.

In addition, with the transmission window 145 of the third embodiment, it was possible to improve plasma ignitability compared to the case where the transmission window 145 of the second embodiment was used. Consequently, with the transmission window 145 of the third embodiment, it is possible to avoid damage to the ceiling wall 111 and to suppress the occurrence of metal contamination while maintaining the range of plasma use conditions and the plasma ignition performance.

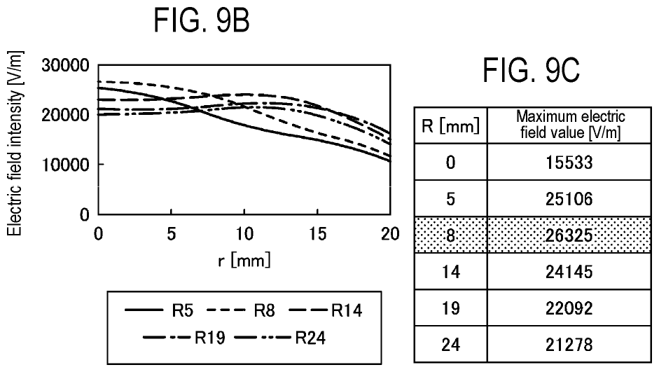

The reason why the configuration of the transmission window 145 of the third embodiment is able to improve plasma ignitability will be described with reference to FIGS. 9A to 9C. FIGS. 9A to 9C are views illustrating an example of electromagnetic field simulation results when microwaves of a predetermined power were radiated from the microwave radiation source 140 when the transmission window 145 according to the third embodiment was used. R illustrated in FIG. 9A indicates the radius of the protrusion 145c. r indicates the distance from the center of the transmission window 145. The center of the transmission window 145 is equal to the center CT of the slot antenna 144 illustrated in FIG. 7B.

The conditions for electromagnetic field simulation were that the transmission window 145 was made of alumina (Al₂O₃), no gas was supplied into the processing container 101, and the gap K was the atmosphere (air). The frequency of the microwaves supplied from the microwave radiation source 140 was set to 860 MHz, and the power of the microwaves was set to 500 W. The gap K was set to 2 mm, and the thickness of the transmission window 145 was set to 8 mm except for the skirt 145a.

The results are shown in FIGS. 9B and 9C. The horizontal axis of FIG. 9B represents the distance r (mm) from the central axis Ax of the transmission window 145 illustrated in FIG. 9A, and the vertical axis represents the electric field intensity (V/m) generated by radiated microwaves. In FIG. 9B, the maximum values of electric field intensities (maximum electric field values) at the distance r from the center of the transmission window 145 were plotted when the radius R of the protrusion 145c (see FIG. 9A and FIG. 7C) was 5 mm (R5), 8 mm (R8), 14 mm (R14), 19 mm (R19), and 24 mm (R24). FIG. 9C is a table showing numerically the maximum electric field values regardless of the distance r when the radius R of the protrusion 145c was 0 mm, 5 mm, 8 mm, 14 mm, 19 mm, and 24 mm. The radius R of the protrusion 145c of 0 mm indicates that the transmission window 145 has the shape of the transmission window 145 according to the second embodiment that does not have the protrusion 145c.

According to the above results, it can be seen that the presence of the protrusion 145c increases the maximum electric field value. When the radius R of the protrusion 145c is 8 mm, that is, when the diameter φ of the protrusion 145c is 16 mm, it is possible to obtain the maximum electric field value due to the radiated microwaves. The higher the maximum electric field value, the better the plasma ignitability. Therefore, by providing the protrusion 145c on the transmission window 145, it is possible to improve plasma ignitability compared to the transmission window 145 according to the second embodiment, which does not have the protrusion 145c.

That is, with the transmission window 145 of the third embodiment, by providing the skirt 145a and the protrusion 145c at predetermined positions of the transmission window 145, it is possible to avoid damage to the ceiling wall 111 and to suppress the occurrence of metal contamination while maintaining the range of plasma use conditions and the plasma ignition performance.

When the dimension of the outer circumference of the protrusion 145c is set to about half the effective wavelength of the microwaves, the electric field intensity can be maximized. Microwaves having a frequency of 860 MHz has a wavelength λ₀ of 348 mm in vacuum. At this time, when the effective wavelength of microwaves at the transmission window 145 is λ_{g}, Equation 1 is established.

$$\frac{{λ}_{g}}{2} = \frac{{λ}_{0}}{2} \times \frac{1}{\sqrt{{ε}_{r}}} \qquad [ Equation 1 ]$$

When the transmission window 145 is made of alumina, the specific dielectric constant Cr of alumina is about 10. Substituting this into Equation 1, half the effective wavelength of microwaves (λ_{g}/2) is calculated to be about 55 from Equation 2.

$$\frac{{λ}_{g}}{2} = \frac{{λ}_{0}}{2} \times \frac{1}{\sqrt{10}} \approx 55 \qquad [ Equation 2 ]$$

When the diameter φ of the protrusion 145c of the transmission window 145 is 16 mm (when the radius R is 8 mm), the outer circumference (2πR) of the protrusion 145c is calculated to be about 50 from Equation 3.

Outer circumference (2πR)=2×3.14×8≈50 [Equation 3]

The reason why the electric field intensity can be maximized when the dimension of the outer circumference of the protrusion 145c is set to half the effective wavelength λ_{g} of the microwaves or made to be close to half the effective wavelength λ_{g} is because the dimension of the outer circumference of the protrusion 145c is effective in increasing an electric field intensity since the electric field is strengthened at a boundary portion having a different specific dielectric constant εᵣ.

The boundary portion having a different specific dielectric constant Cr refers to the outer circumferential portion of the alumina protrusion 145c, which is the boundary with the air layer of the gap K, in the case of the ceiling wall 111, and refers to the boundary portion between the slot S that is air and the slot antenna 144 that is made of aluminum in the case of the slot S. Therefore, when the dimension of the outer circumference of the slot S is set to half the effective wavelength λ_{g} of the microwaves or made to be close to half the effective wavelength λ_{g}, in the slot antenna 144, the intensities of a magnetic field H and an electric field E occurring at the boundary between the slot S and the slot antenna 144 illustrated in FIG. 7B can be maximized.

In addition, the dimension of the outer circumference of the protrusion 145c is a parameter that leads to the maximum of electric field E intensity. Referring to FIG. 7C, when the dimension of the outer circumference of the protrusion 145c is set to half the effective wavelength λ_{g} of microwaves or made to be close to half the effective wavelength λ_{g} of microwaves, the intensities of a magnetic field H and an electric field E occurring at the outer circumference (the boundary portion) of the protrusion 145c can be maximized. The above-mentioned “set to half the effective wavelength λ_{g} of the microwave or made to be close to half the effective wavelength λ_{g}” generally refers to λ_{g}/2±λ_{g}/10.

As described above, with the plasma processing apparatus 100 and the microwave radiation source 140 of the present embodiment, it is possible to suppress the occurrence of contamination due to damage in an opening that radiates microwaves.

In particular, when the transmission window 145 of the third embodiment is used, as in the case where the transmission window 145 of the second embodiment is used, it is possible to stabilize plasma and to widen the range of plasma use conditions. Furthermore, it is possible to enhance plasma ignitability compared to the transmission window 145 of the second embodiment.

As illustrated in FIG. 4, when the transmission window 145 of the first embodiment was used, the number of yttrium (Y) precipitated as contaminations was reduced compared to the case where the transmission window 145′ of the reference example was used. Although not illustrated, in the case where the transmission windows 145 of the second and third embodiments, the numbers of yttrium (Y) precipitated as contaminations were similarly reduced compared to the case in which the transmission window 145′ of the reference example was used.

According to an aspect, it is possible to suppress the occurrence of contamination near an opening that radiates microwaves.

The plasma processing apparatus 100 and the microwave radiation source 140 according to the embodiments disclosed herein should be considered as being exemplary in all respect and not restrictive. The embodiments may be modified and improved in various forms without departing from the scope and spirit of the appended claims. The matters described in the aforementioned embodiments may have other configurations to the extent that they are not contradictory, and may be combined to the extent that they are not contradictory.

What is claimed is:

1. A plasma processing apparatus comprising:
a processing container including an opening provided in a ceiling wall of the processing container; and
a microwave radiation source,
wherein the microwave radiation source includes:
a slot antenna including a slot and configured to radiate microwaves from the slot; and
a transmission window configured to close the opening and to radiate the microwaves from the slot into the processing container, and
wherein the transmission window includes:
a first surface including a skirt which suspends to cover a side wall of the opening; and
a second surface which is an opposite surface to the first surface and faces the slot antenna with a gap between the slot antenna and the second surface.

2. The plasma processing apparatus of claim 1, wherein the second surface includes a protrusion that is in contact with a central portion of the slot antenna, and the second surface is configured, in a surface other than the protrusion, to face the slot antenna with the gap between the slot antenna and the second surface.

3. The plasma processing apparatus of claim 2, wherein the slot is formed in an arcuate shape or an annular shape around the central portion, and
a contact surface of the protrusion is a circle having a diameter equal to or smaller than an inner diameter of the slot and does not overlap inside of the slot.

4. The plasma processing apparatus of claim 3, wherein the contact surface of the protrusion is a circle having a smaller diameter than the inner diameter of the slot and is in contact with the central portion to be spaced apart from the slot.

5. The plasma processing apparatus of claim 4, wherein the protrusion has a height of 2 mm or less.

6. The plasma processing apparatus of claim 5, wherein a dimension of an outer circumference of the protrusion is half an effective wavelength λg of the microwaves.

7. The plasma processing apparatus of claim 6, wherein a height of an end portion of the skirt is aligned with a height of an end portion of the opening.

8. The plasma processing apparatus of claim 7, wherein the skirt is formed along an entire circumference of the side wall of the opening on an outer circumference side of the slot.

9. The plasma processing apparatus of claim 8, wherein the skirt is formed inside the side wall of the transmission window.

10. The plasma processing apparatus of claim 2, wherein the protrusion has a height of 2 mm or less.

11. The plasma processing apparatus of claim 2, wherein a dimension of an outer circumference of the protrusion is half an effective wavelength λg of the microwaves.

12. The plasma processing apparatus of claim 1, wherein a height of an end portion of the skirt is aligned with a height of an end portion of the opening.

13. The plasma processing apparatus of claim 1, wherein the skirt is formed along an entire circumference of the side wall of the opening on an outer circumference side of the slot.

14. The plasma processing apparatus of claim 1, wherein the skirt is formed inside the side wall of the transmission window.

15. A microwave radiation source used in a plasma processing apparatus which includes a processing container having an opening provided in a ceiling wall of the processing container, the microwave radiation source comprising:
a slot antenna including a slot and configured to radiate microwaves from the slot; and
a transmission window configured to close the opening and to radiate the microwaves from the slot into the processing container,
wherein the transmission window includes:
a first surface including a skirt which suspends to cover a side wall of the opening; and
a second surface which is an opposite surface to the first surface and faces the slot antenna with a gap between the slot antenna and the second surface.
